(19) United States
(12) Patent Application Publication
(10) Pub. No.: US 2024/0426682 A1
(43) Pub. Date: Dec. 26, 2024

(54) SEMICONDUCTOR DIE LEVEL STRESS DETECTION IN PACKAGE UTILIZING STRAIN GAUGE STRUCTURES

(71) Applicant: Qorvo US, Inc., Greensboro, NC (US)

(72) Inventors: Thomas Scott Morris, Lewisville, NC (US); Peter Cotterill, Cary, NC (US)

(21) Appl. No.: 18/754,417

(22) Filed: Jun. 26, 2024

Related U.S. Application Data
(60) Provisional application No. 63/523,232, filed on Jun. 26, 2023.

(51) Int. Cl. G01L 1/22

(52) U.S. Cl. CPC G01L 1/2262; G01L 1/2287

(57) ABSTRACT

In some embodiments, a method of measuring strain on a semiconductor substrate of a semiconductor die is disclosed. The semiconductor die further includes a Back End of Line (BEOL) positioned on the semiconductor substrate that includes a metallic structure. In some embodiments, the method includes transmitting a measurement signal into the metallic structure. In some embodiments, the method further includes detecting a resistance of the metallic structure in response to the transmission of the measurement signal. In some embodiments, the method includes determining a strain of the semiconductor die based on the resistance of the metallic structure.

### RELATED APPLICATIONS

This application claims the benefit of provisional patent application Ser. No. 63/523,232, filed Jun. 26, 2023, the disclosure of which is hereby incorporated herein by reference in its entirety.

### FIELD OF THE DISCLOSURE

This disclosure relates to systems and methods of testing the structural integrity of semiconductor dies.

### BACKGROUND

The thickness of integrated circuit (IC) packages is being driven down and reduced due to industry pressure to provide thinner IC packages. There has been a significant reduction in the thickness of IC packages in recent years and the projected trend is that IC packages will continue to be thinner. One method of reducing the thickness of IC packages is to thin semiconductor dies mounted to the laminate of the IC packages.

The problem is that thinning semiconductor dies threatens their structural integrity. Thus, some IC manufacturers are hesitant to thin the semiconductor die for fear that the IC package will not be able to bear the strain placed on the semiconductor die when the semiconductor die is thinner. Thus, being able to accurately measure the strain on the semiconductor die is important if semiconductor dies are to be thinned in order to continue to thin IC packages.

### SUMMARY

In some embodiments, a method of measuring strain in a semiconductor substrate of a semiconductor die, the semiconductor die further including a Back End of Line (BEOL) metallization on the semiconductor substrate that includes a metallic structure, the method includes: transmitting a measurement signal into the metallic structure; detecting a resistance of the metallic structure in response to the transmission of the measurement signal; and determining a strain of the semiconductor die based on the resistance of the metallic structure. In some embodiments, the resistance is a first resistance of the metallic structure and the strain is a first strain of the semiconductor die having a first thickness, the method further includes: reducing a first thickness of the semiconductor die to a second thickness that is less than the first thickness; retransmitting the measurement signal into the metallic structure when the semiconductor die is at the second thickness; detecting a second resistance of the metallic structure in response to the retransmission of the measurement signal; and determining a second strain of the semiconductor die based on the second resistance of the metallic structure. In some embodiments, the second resistance is higher than the first resistance thereby indicating that the second strain is higher than the first strain. In some embodiments, the metallic structure includes a meandering conductive path wherein: the meandering conductive path defining a long path axis; and the strain is measured around the long path axis. In some embodiments, the meandering path is a first meandering path; the long path axis is a first long path axis; the strain is a first strain; the strain axis is a first strain axis; the measurement signal is a first measurement signal; and the metallic structure further includes a second meandering path defining a second long axis that is substantially orthogonal to the first long path axis. In some embodiments, the method further includes transmitting a second measurement signal into the second meandering path; detecting a second resistance of the second meandering path in response to the transmission of the second measurement signal; and determining a second strain of the semiconductor die based on the second resistance of the second meandering path, wherein the second strain is measured around the second long path axis. In some embodiments, the first meandering path is positioned in a first conductive layer of the BEOL metallization and the second meandering path is positioned in a second conductive layer of the BEOL metallization. In some embodiments, detecting a resistance of the metallic structure in response to the transmission of the measurement signal includes detecting the resistance of the metallic structure in response to the transmission of the measurement signal with a resistance detection circuit. In some embodiments, the resistance detection circuit has a Wheatstone Bridge configuration. In some embodiments, the semiconductor die is mounted on a package body and the resistance detection circuit is formed by a metallic structure integrated into the package body. In some embodiments, the method further includes mounting the semiconductor die on a package substrate prior to transmitting the measurement signal into the metallic structure.

In some embodiments, a method of measuring strain in a semiconductor substrate of a semiconductor die, the semiconductor die further including a BEOL metallization that includes a meandering conductive path, the method includes: transmitting a measurement signal into the meandering conductive path, wherein the meandering path defines a long path axis; detecting a resistance of the meandering conductive path in response to the transmission of the measurement signal; and determining a strain of the semiconductor die based on the resistance of the meandering path, wherein the strain is measured around the long path axis. In some embodiments, the meandering path includes: a first plurality of conductive segments, each of the first plurality of conductive segments has a long segment axis that extend parallel to the long path axis; and a second plurality of conductive segments, each of the second plurality of conductive segments connects different pairs of the first plurality of conductive segments. In some embodiments, the meandering path is positioned in a first conductive layer of the BEOL metallization. In some embodiments, the method further includes transmitting a second measurement signal into a second meandering conductive path in the BEOL metallization, wherein: the meandering path is a first meandering path; the long path axis is a first long path axis; the measurement signal is a first measurement signal; the second meandering path defines a second long path axis substantially orthogonal to the first long path axis; detecting a second resistance of the second meandering conductive path in response to the transmission of the second measurement signal, wherein the resistance is a first resistance; and determining a second strain of the semiconductor die based on the second of the second meandering path, wherein the second strain is measured around the second long path axis, wherein the strain is a first strain. In some embodiments, the first meandering path is in a first conductive layer of the BEOL; and the second meandering path is in a second conductive layer of the BEOL metallization. In some embodiments, transmitting the first measurement signal into the first meandering conductive path includes transmitting the first measurement signal into the first meandering conductive path with a first Wheatstone Bridge circuit; and transmitting the second measurement signal into the second meandering conductive path includes transmitting the second measurement signal into the second meandering conductive path with a second Wheatstone Bridge circuit. In some embodiments, transmitting the first measurement signal into the first meandering conductive path includes transmitting the first measurement signal into the first meandering conductive path with a Wheatstone Bridge circuit; and transmitting the second measurement signal into the second meandering conductive path includes transmitting the second measurement signal into the second meandering conductive path with the Wheatstone Bridge circuit. In some embodiments, the semiconductor die is mounted on a package body; transmitting the measurement signal into the meandering conductive path includes transmitting the measurement signal into the meandering conductive path with a Wheatstone Bridge circuit; and the Wheatstone Bridge circuit is formed in a conductive structure integrated into the package body. In some embodiments, the method further includes mounting the semiconductor die on a package substrate prior to transmitting the measurement signal into the meandering conductive path.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a semiconductor die, in accordance with some embodiments;

FIG. 2 is an integrated circuit (IC) package, in accordance with some embodiments;

FIG. 3 is a strain measurement circuit, in accordance with some embodiments;

FIG. 4 is a strain measurement circuit, in accordance with some embodiments;

FIG. 5 is a strain measurement circuit, in accordance with some embodiments;

FIG. 6 is a flow diagram of a method of measuring strain in a semiconductor substrate of a semiconductor die, in accordance with some embodiments; and

FIG. 7 illustrates a computer device or a computer, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

This disclosure relates generally to systems and methods of measuring the strain on the semiconductor substrate of a semiconductor die. In particular, a metallic structure is formed in a Back End of Line (BEOL) metallization of the semiconductor die. A measurement signal is then transmitted into the metallic structure and the resistance of the metallic structure is measured. The resistance of the metallic structure is related to the amount that the metallic structure has been bent due to the stress put on the BEOL metallization. As such, this is directly related to the amount of bending being placed on the semiconductor die due to the strain. Accordingly, the strain on the semiconductor die can be measured thereby allowing semiconductor manufacturers to determine how thin the semiconductor substrate can be while maintaining an acceptable amount of strain on the semiconductor substrate.

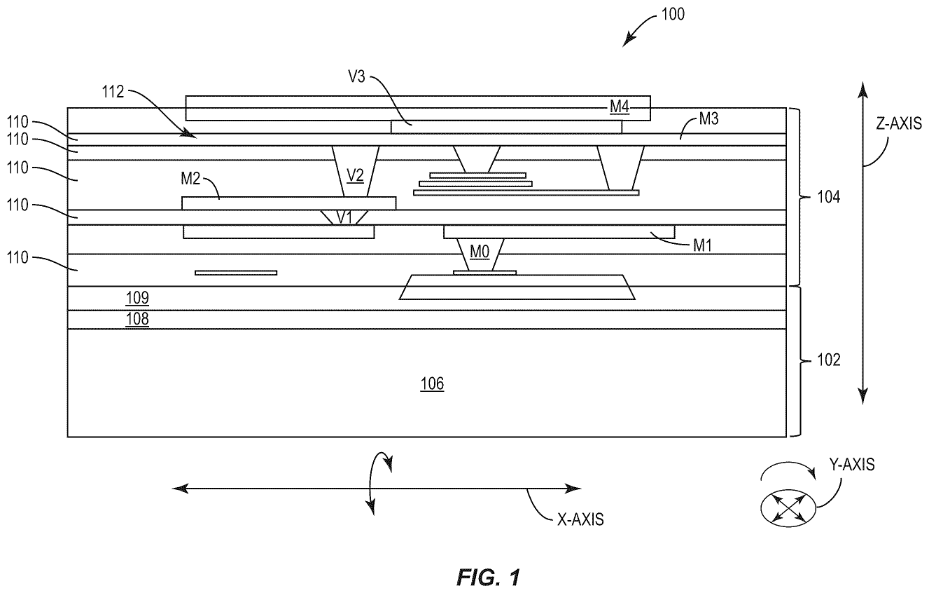

FIG. 1 is a semiconductor die 100, in accordance with some embodiments.

The semiconductor die 100 includes a semiconductor substrate 102 and a BEOL metallization 104. Layers of the semiconductor die 100 are stacked relative to a Z-axis, which is considered a vertical axis. There are two horizonal axes that are both orthogonal to the Z-axis. The Y-axis is a first horizontal axis that is orthogonal to the Z-axis. In some embodiments, the Y-axis is parallel to the direction of extension of gates or fingers formed on the semiconductor substrate 102. In FIG. 1, the Y-axis extends out of and into the page. The X-axis is another horizontal axis that is orthogonal to both the Y-axis and the Z-axis.

The semiconductor substrate 102 includes a bulk wafer 106, a Buried Oxide (BOX) layer 108 formed on and over the bulk wafer 106, and a Front End of Line (FEOL) portion 109 formed on and over the BOX layer 108. Note that, in some embodiments, the BOX layer 108 is not included.

An FEOL portion refers to the portion of a semiconductor die (e.g., the semiconductor die 100) that is formed by an FEOL process. An FEOL portion includes portions in a semiconductor substrate that form active semiconductor devices. An FEOL portion thus includes one or more semiconductor layers with active semiconductor regions for active semiconductor devices. Generally, these active semiconductor regions include doped regions with p-type and/or n-type doping. An FEOL portion also includes one or more conductive layers that form contacts of active semiconductor devices.

A BEOL metallization (e.g., the BEOL metallization 104) refers to a section of a semiconductor die (e.g., the semiconductor die 100) that is formed during a BEOL process. A BEOL metallization includes a conductive structure that interconnects active semiconductor devices in a FEOL portion so that a FEOL portion and a BEOL metallization form an integrated circuit (IC). In some embodiments, a BEOL metallization includes various metallic layers that are interconnected by vias and are encapsulated by an insulating material. A BEOL metallization may form metallic traces interconnected by vias that interconnect active semiconductor devices in a FEOL portion.

The bulk wafer 106 is formed from a semiconductor material such as silicon, silicon germanium (SiGe), gallium arsenic, gallium nitride, or other suitable semiconductor materials. The bulk wafer 106 provides the structural integrity of the semiconductor substrate 102 and is typically the thickest portion of the semiconductor substrate 102.

The BOX layer 108 is formed from an oxidized semiconductor material, such as silicon oxide or germanium oxide. The BOX layer 108 is configured as an electrical insulator between the bulk wafer 106 and the FEOL portion 109.

The BOX layer 108 is sometimes used in high-frequency radio frequency (RF) and radiation-sensitive applications to reduce short-channel effects between the FEOL portion 109 and the bulk wafer 106. In some embodiments, the BOX layer 108 is not provided.

The FEOL portion 109 is formed from a semiconductor material such as silicon, silicon germanium (SiGe), gallium arsenic, gallium nitride, or other suitable semiconductor materials. The FEOL portion 109 includes active regions of active semiconductor devices, such as field effect transistors (FETs), bipolar junction transistors (BJTs), diodes, and/or the like. The FEOL portion 109 includes active regions that are doped either with an n-type dopant or a p-type dopant to provide the functionality necessary for active semiconductor devices.

The BEOL metallization 104 is formed on and over the FEOL portion 109. The BEOL metallization 104 is formed from various insulating layers 110 and a conductive structure 112 that is integrated into the insulating layers 110. The bottom most portion of the conductive structure 112 is a conductive layer M0, which includes conductive contacts and conductive trances that are formed on the FEOL portion 109. The conductive layer M0 includes contacts that form the contacts of the active semiconductor components and the connecting components that connect to the next highest conductive layer M1 in the conductive structure 112.

From lowest to highest, the conductive structure 112 (also referred to as the metallic structure 112) includes the conductive layers M1, M2, M3, M4 (also referred to as the metal layers M1, M2, M3, M4). In other embodiments, there are more conductive layers and there are less conductive layers. From lowest to highest, the metallic structure 112 includes conductive via layers V1, V2, V3 between the conductive layers M1, M2, M3, M4. The conductive via layers V1, V2, V3 include conductive vias that interconnect conductive traces, contacts, and other components in the conductive layers M1, M2, M3, M4. In this manner, the metallic structure 112 and the FEOL portion 109 form one or more ICs. The conductive layer M4 is the top most conductive layer in this embodiment. As such, the conductive layer M4 forms conductive components to connect to external components that are outside of the semiconductor die 100.

In some embodiments, the BEOL metallization 104 includes at least one BEOL metal layer. Structures (such as the meandering paths described below) are formed in one or more BEOL metal layers. For example, in some embodiments, the two meandering paths (discussed below) are formed in a single BEOL metal layer. In other embodiments, one of the meandering paths is formed in one BEOL metal layer and the other meandering path is formed in another BEOL metal layer. In still other embodiments, at least one of the meandering paths is formed in multiple BEOL metal layers so that different portions of the meandering path are positioned in different BEOL metal layers. In some embodiments, both meandering paths are formed in multiple BEOL metal layers. In other words, this disclosure is not constrained to any particular number of BEOL metal layers for the meandering paths.

The bulk wafer 106 provides the structural integrity of the semiconductor die 100. As more and more stress is applied to the semiconductor die 100, the semiconductor substrate 102 bends due to strain around the X-axis. Furthermore, as more and more stress is applied to the semiconductor die 100, the semiconductor substrate 102 bends around the Y-axis. Accordingly, bending around the X-axis will cause stretching of the conductive structure 112 with respect to the Y-axis. Furthermore, bending around the Y-axis will cause stretching of the conductive structure 112 with respect to the X-axis. This disclosure takes advantage of this stretching to measure the strain on the semiconductor die 100.

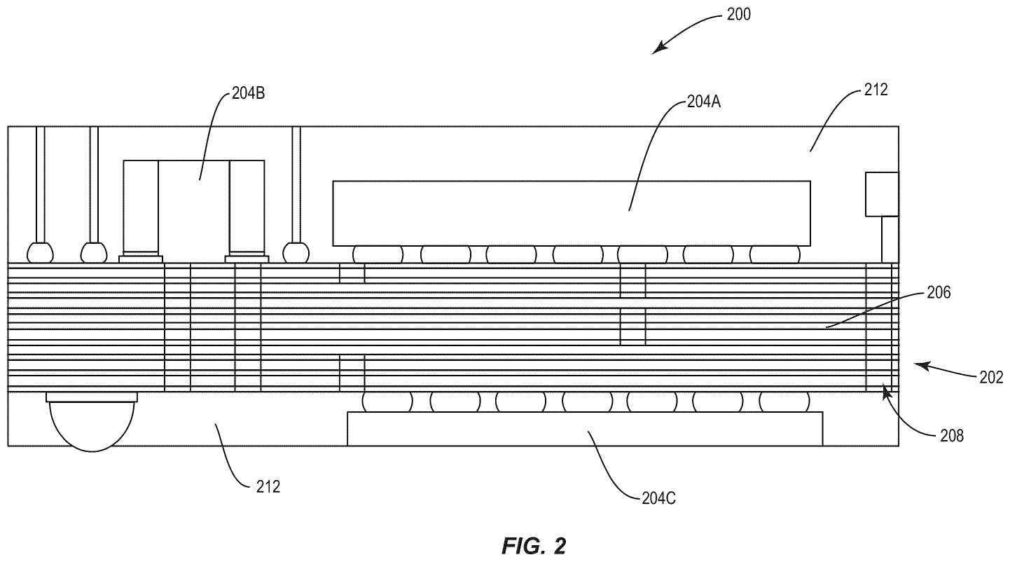

FIG. 2 is an IC package 200, in accordance with some embodiments.

In some embodiments, the IC package 200 is a double-sided IC package. In particular, the IC package 200 includes a package substrate 202 and semiconductor dies 204A, 204B, 204C mounted on a top surface and on a bottom surface of the package substrate 202. More specifically, the semiconductor dies 204A, 204B are mounted on the top surface of the package substrate 202 and the semiconductor die 204C is mounted on a bottom surface of the package substrate 202.

The package substrate 202 includes a package body 206 and a conductive structure 208 (e.g., a metallic structure) integrated into the package body 206. The package body 206 is formed from a material such as laminate, ceramic, and/or the like. The conductive structure 208 forms interconnections between the semiconductor dies 204A, 204B, 204C and to connecting components forming connections external to the IC package 200.

In some embodiments, each of the semiconductor dies 204A, 204B, 204C is configured like the semiconductor die 100 shown in FIG. 1 or in a similar manner. In this case, the top most conductive layer in the BEOL metallization (e.g., the conductive layer M4 in FIG. 1) is mounted to and forms connections with the conductive structure 208 in the package body 206. More specifically, the top most conductive layer in the BEOL metallization of the semiconductor dies 204A, 204B are mounted on the top surface of the package body 206 to form connections with the conductive structure 208. The top most conductive layer in the semiconductor die 204C, 204B in the BEOL metallization are mounted on the bottom surface of the package body 206 to form connections with the conductive structure 208. An overmold 212 is formed to surround the semiconductor dies 204A, 204B and the top surface of the package body 206. An overmold 212 is formed to surround the semiconductor die 204C and the bottom surface of the package body 206.

There is more and more incentive on IC manufacturers to thin a thickness of the IC package 200. One technique for doing this is to thin the bulk wafer of the semiconductor dies 204A, 204B, 204C, especially the bulk wafer of the semiconductor die 204C mounted to the bottom surface of the package body 206. In some embodiments, there is an incentive to thin the bulk wafer of the semiconductor die 204C to a thickness of 45 micrometers or less. There is also an incentive to thin all of the semiconductor substrates of all of the semiconductor dies 204A, 204B, 204C. However, in order to do this, semiconductor manufacturers should ensure that this does not cause excessive strain on the semiconductor substrates of the semiconductor dies 204A, 204B, 204C, which risks their structural integrities, respectively. Thus, being able to measure the strain created on the semiconductor dies 204A, 204B, 204C at different thicknesses of the semiconductor substrates is important if the semiconductor substrates are to be continuously thinned in a manner that does not threaten the structural integrity of the semiconductor dies 204A, 204B, 204C.

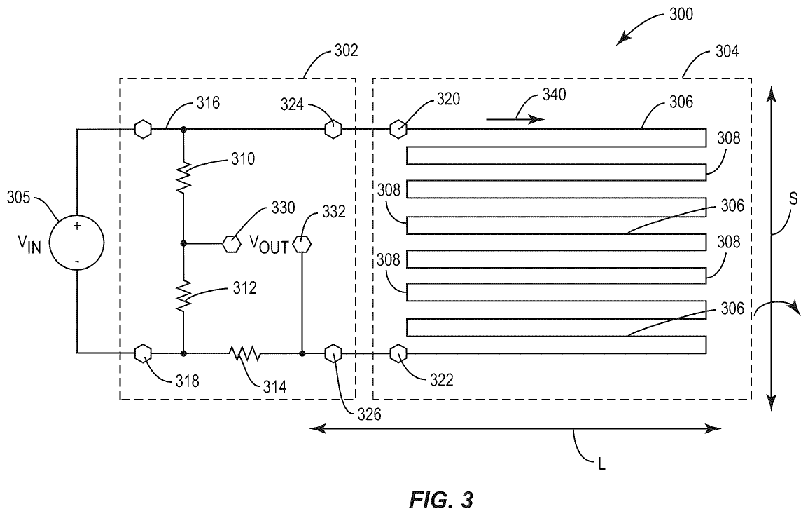

FIG. 3 is a strain measurement circuit 300, in accordance with some embodiments.

The strain measurement circuit 300 includes a resistance detection circuit 302 and a meandering conductive path 304. The meandering conductive path 304 defines a long axis L and a short axis S. The long axis L is substantially orthogonal to the short axis S. This means that the long axis L has greater length along the long axis L than along the short axis S. In this embodiment, the meandering conductive path 304 includes long conductive segments 306 (not all labeled for the sake of clarity) that extend parallel to the long axis L. The long conductive segments 306 are connected by short conductive segments 308 that extend parallel with the short axis S. Strain around the short axis S will cause the long conductive segments 306 to stretch in a direction parallel to the long axis L. This, in turn, results in the resistance of the long conductive segments 306 to increase (the long axis L is normal to the area of the long conductive segments 306 that decreases due to strain about the short axis S) and, thus, the resistance of the meandering conductive path 304 increases.

The meandering conductive path 304 is provided in the conductive structure (e.g., the conductive structure 112 in FIG. 1) of a BEOL metallization (e.g., the BEOL metallization 104 in FIG. 1) of a semiconductor die (e.g. the semiconductor die 100 in FIG. 1). For example, the meandering conductive path 304 is formed in one of the conductive layers (e.g., one of the conductive layers M0, M1, M2, M3, M4) of the BEOL metallization. In other embodiments, the meandering conductive path 304 is formed in multiple different conductive layers (multiple different ones of the conductive layers M0, M1, M2, M3, M4). In this case, different portions of the meandering conductive path 304 shown in FIG. 3 are formed in different BEOL conductive layers.

Accordingly, the change in the length of the long conductive segments 306 thereby is directly related to a change in a length of the semiconductor substrate (e.g., the semiconductor substrate 102 in FIG. 1). This change in length thus indicates the strain of the semiconductor substrate about the short axis S, which is substantially orthogonal to the long axis L of the meandering conductive path 304. As a result, by measuring the resistance of the meandering conductive path 304, the strain about the short axis S of the semiconductor substrate can also be determined and measured as well.

The resistance detection circuit 302 is configured to measure the resistance of the meandering conductive path 304. In FIG. 3, the resistance detection circuit 302 is a Wheatstone Bridge circuit having a Wheatstone Bridge configuration. However, the resistance detection circuit 302 can have other configurations so long as the resistance detection circuit 302 is configured to measure the resistance of the meandering conductive path 304.

In some embodiments, the resistance detection circuit 302 includes a power source 305. However, in FIG. 3, the power source 305 is external to the resistance detection circuit 302. The power source 305 is a battery or circuitry powered by a battery, in accordance with some embodiments. In some embodiments, the resistance detection circuit 302 is formed in a conductive structure (e.g. the conductive structure 208 in FIG. 2) in a package body (e.g., the package body 206 in FIG. 2).

The resistance detection circuit 302 includes resistors 310, 312, 314. A first power node 316 is connected to the power source 305 to provide a power source voltage (e.g., VDD) and a second power node 318 is connected to the power source 305 to provide a reference voltage (e.g., ground). In some embodiments, the first power node 316 and the second power node 318 are provided as solder pads that are formed in a metallic structure (e.g., the metallic structure 208 in FIG. 2) in the package body (e.g., the package body 206 in FIG. 2). The resistor 310 is connected between the first power node 316 and a node NM. The resistor 312 is connected between the node NM and the second power node 318.

The conductive meandering path 304 is connected at one end to a connection node 320 and at an opposite end to a connection node 322. In some embodiments, the connection node 320 and the connection node 322 are solder bumps connected to the top most layer (e.g., the conductive layer M4 in FIG. 1) of the BEOL metallization of the semiconductor die. The connection node 320 is directly connected to a connection node 324 in the resistance detection circuit 302. The connection node 322 is directly connected to a connection node 326 in the resistance detection circuit 302. The connection node 324 is directly connected to the connection node 320. The resistor 314 is connected between the connection node 326 and the second power node 318. In some embodiments, the connection node 324 and the connection node 326 are formed as solder pads in the metallic structure (e.g., the metallic structure 208 in FIG. 2) in the package body (e.g., the package body 206 in FIG. 2). Also in some embodiments, the resistors 310, 312, 314 are fixed resistors formed as surface mount device (SMD) resistors in the metallic structure (e.g., the metallic structure 208 in FIG. 2) in the package body (e.g., the package body 206 in FIG. 2).

A connection node 330 and a connection node 332 are provided to measure a voltage Vout. In some embodiments, the connection node 330 and the connection node 332 are formed as solder pads in the metallic structure (e.g., the metallic structure 208 in FIG. 2) in the package body (e.g., the package body 206 in FIG. 2). The connection node 330 is directly connected to the node NM. The connection node 332 is directly connected to the connection node 326.

The voltage Vout is directly related to the resistance of the meandering conductive path 304. More specifically, the power source 305 is configured to generate a voltage Vin between the first power node 316 and the second power node 318. The resistances of the resistors 310, 312, 314 are known. The voltage Vin thus generates a measurement signal 340 that propagates through the meandering conductive path 304. If the potential difference between the resistor 310 and the meandering conductive path 304 is the same as the resistance between the resistor 312 and the resistor 314, then the measurement signal 340 results in the voltage Vout being equal to zero. Accordingly, the resistance of the meandering conductive path 304 would be known, since the resistance of the resistors 310, 312, 314 are known. However, if the potential difference between the resistor 310 and the meandering conductive path 304 is not the same as the resistance between the resistor 312 and the resistor 314, then the measurement signal 340 results in the voltage Vout being non-zero. The voltage level of the voltage Vout is directly related to the resistance of the meandering conductive path 304, resulting in the measurement signal 340 and the resistance of the meandering conductive path 304 to be capable of being calculated based on the voltage level of Vout. In this manner, the resistance detection circuit 302 is configured to measure the resistance of the meandering conductive path 304.

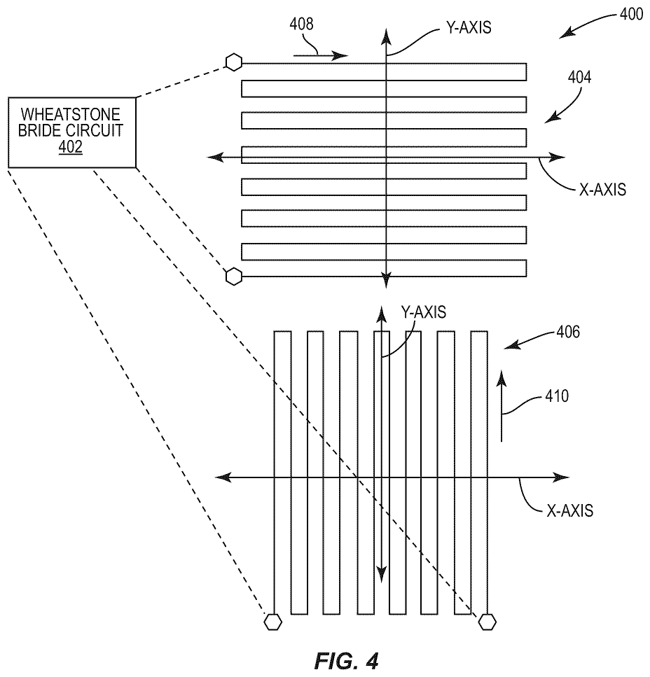

FIG. 4 is a strain measurement circuit 400, in accordance with some embodiments.

The strain measurement circuit 400 include a resistance detection circuit 402, a meandering conductive path 404, and a meandering path 406. The resistance detection circuit 402 is configured to generate a measurement signal 408 in order to measure a resistance of the meandering conductive path 404. The resistance detection circuit 402 is also configured to generate a measurement signal 410 to measure a resistance of the meandering path 406.

In some embodiments, the resistance detection circuit 402 is provided in the same manner as the resistance detection circuit 302 in FIG. 3. The resistance detection circuit 402 generates both the measurement signal 408 and the measurement signal 410. In some embodiments, the resistance detection circuit 402 is a Wheatstone Bridge circuit 402. In some embodiments, switching device(s) (not explicitly shown) are provided between the Wheatstone Bridge circuit 402, the meandering conductive path 404, and the meandering path 406 so as to selectively connect the Wheatstone Bridge circuit 402 to the meandering conductive path 404 to provide the measurement signal 408 during one time period and so as to selectively connect the Wheatstone Bridge circuit 402 to the meandering path 406 to provide the measurement signal 410 during a different time period. In some embodiments, the power source (e.g., the power source 305 in FIG. 3) is internal to the Wheatstone Bridge circuit 402. In other embodiments, the power source is external to the Wheatstone Bridge circuit 402.

The meandering conductive path 404 is provided in the same manner as the meandering conductive path 304 in FIG. 3. However, in this embodiment, a long axis (e.g., the long axis L in FIG. 3) of the meandering conductive path 404 is parallel with the X-axis (see FIG. 1) and a short axis (e.g., the short axis S in FIG. 3) is parallel with the Y-axis (see FIG. 1). The resistance of the meandering conductive path 404 thus indicates the strain about the Y-axis as a result of an elongation of the meandering conductive path 404 with respect to the X-axis. In some embodiments, the meandering conductive path 404 is formed in a single one of the conductive layers M0, M1, M2, M3, M4 in FIG. 1. In other embodiments, the meandering conductive path 404 is formed in multiple different conductive layers (multiple different ones of the conductive layers M0, M1, M2, M3, M4 in FIG. 1). In this case, different portions of the meandering conductive path 404 shown in FIG. 4 are formed in different BEOL conductive layers.

The meandering path 406 is provided in the same manner as the meandering conductive path 304 in FIG. 3. However, in this embodiment, a long axis (e.g., the long axis L in FIG. 3) of the meandering path 406 is parallel with the Y-axis and a short axis (e.g., the short axis S in FIG. 3) is parallel with the X-axis. The resistance of the meandering path 406 thus indicates the strain about the X-axis as a result of an elongation of the meandering path 406 with respect to the Y-axis. In some embodiments, the meandering path 406 is formed is formed in a single one of the conductive layers M0, M1, M2, M3, M4 in FIG. 1. In other embodiments, the meandering path 406 is formed in multiple different conductive layers (multiple different ones of the conductive layers M0, M1, M2, M3, M4 in FIG. 1). In this case, different portions of the meandering conductive path 406 shown in FIG. 4 are formed in different BEOL conductive layers.

Accordingly, the strain measurement circuit 400 is configured to measure the strain about both the X-axis and the Y-axis. Since the X-axis and the Y-axis are orthogonal, a strain vector for the strain in a semiconductor substrate (e.g., the semiconductor substrate 102 in FIG. 1) can be provided at a particular thickness of the bulk wafer 106 in FIG. 1. Both the meandering conductive path 404 and the meandering path 406 are provided in a BEOL metallization (e.g., the BEOL metallization 104 in FIG. 1) of the semiconductor die (e.g., the semiconductor die 100 in FIG. 1). In some embodiments, the meandering conductive path 404 is formed in one conductive layer of the BEOL metallization and the meandering path 406 is provided in a different conductive layer of the BEOL metallization. For example, in one embodiment, the meandering conductive path 404 is provided in the conductive layer M1 of the BEOL metallization 104 in FIG. 1 while the meandering path 406 is provided in the conductive layer M3 of the BEOL metallization 104 in FIG. 1.

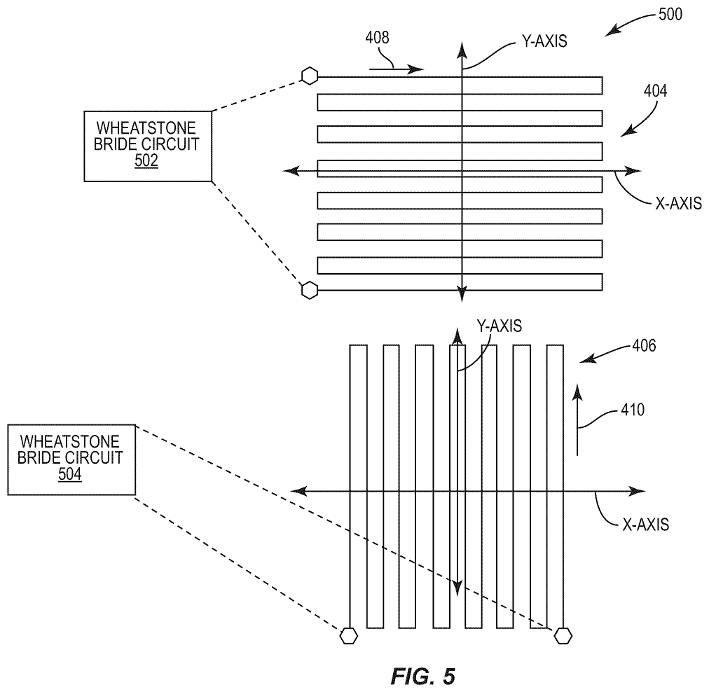

FIG. 5 is a strain measurement circuit 500, in accordance with some embodiments.

The strain measurement circuit 500 includes the same meandering conductive path 404 and the same meandering path 406 described above with respect to FIG. 4. However, in FIG. 5, the strain measurement circuit 500 includes a resistance detection circuit 502 (in this example, a Wheatstone Bridge Circuit 502) that is coupled to the meandering conductive path 404 and a resistance detection circuit 504 (in this example, a Wheatstone Bridge Circuit 504) that is coupled to the meandering path 406.

In some embodiments, the resistance detection circuit 502 is configured to generate the measurement signal 408 to measure the resistance of the meandering conductive path 404. In some embodiments, the resistance detection circuit 502 is provided in the same manner as the resistance detection circuit 302 in FIG. 3. In some embodiments, switching circuitry is not needed between the resistance detection circuit 502 and the meandering conductive path 404. In some embodiments, a power source (e.g., the power source 305 in FIG. 3) is internal to the Wheatstone Bridge circuit 502. In other embodiments, the power source is external to the Wheatstone Bridge circuit 502.

In some embodiments, the resistance detection circuit 504 is configured to generate the measurement signal 410 to measure the resistance of the meandering path 406. In some embodiments, the resistance detection circuit 504 is provided in the same manner as the resistance detection circuit 302 in FIG. 3. In some embodiments, switching circuitry is not needed between the resistance detection circuit 504 and the meandering path 406. In some embodiments, the power source (e.g., the power source 305 in FIG. 3) is internal to the Wheatstone Bridge circuit 504. In other embodiments, the power source is external to the Wheatstone Bridge circuit 504.

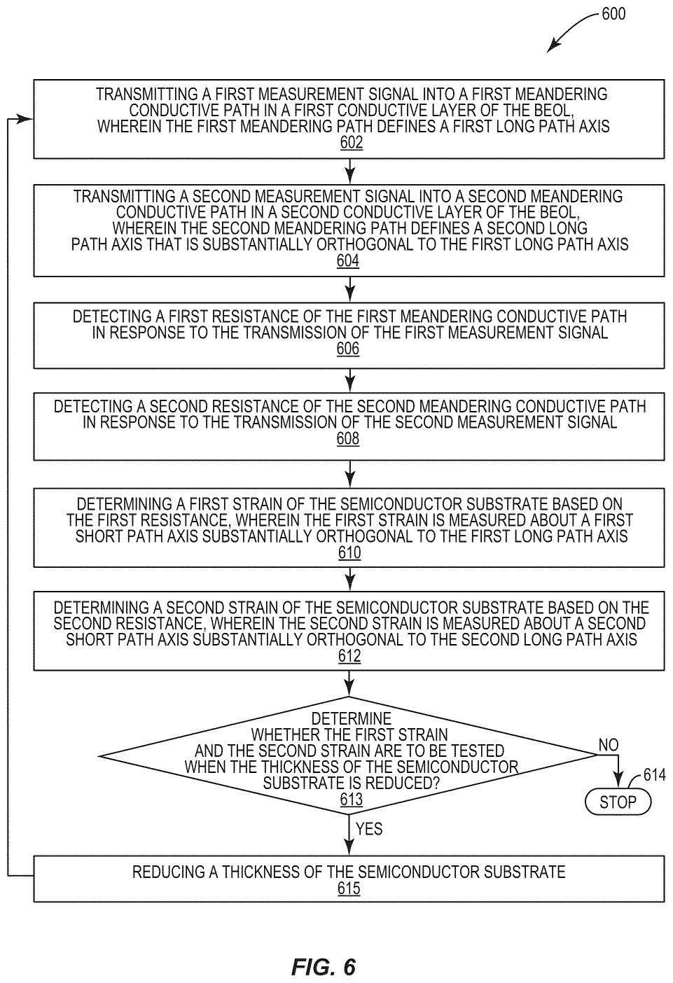

FIG. 6 is a flow diagram 600 of a method of measuring strain in a semiconductor substrate of a semiconductor die, in accordance with some embodiments.

An example of the semiconductor die is the semiconductor die 100 in FIG. 1. An example of the semiconductor substrate is the semiconductor substrate 102 in FIG. 1. The flow diagram 600 includes procedures 602-615. The procedures 602-615 can be used to test the strains in any type of semiconductor die. In some embodiments, the semiconductor dies are used in RF applications. However, any other type of semiconductor die used to implement any other type of application may also be tested through the procedures in the flow diagram 600. Flow begins at procedure 602.

At the procedure 602, a first measurement signal is transmitted into a first meandering conductive path in a first conductive layer of the BEOL metallization, wherein the first meandering path defines a first long path axis. An example of the BEOL metallization is the BEOL metallization 104 in FIG. 1. An example of the first measurement signal is the measurement signal 408 in FIG. 4 and FIG. 5. An example of the first meandering conductive path is the meandering conductive path 404 in FIG. 4 and FIG. 5. An example of the first conductive layer is any one of the conductive layers M1, M2, M3, or M4 in FIG. 1. An example of the first long path axis is the X-axis in FIG. 4 and FIG. 5. In some embodiments, the procedure 602 is performed by the Wheatstone Bridge circuit 402 in FIG. 4 or the Wheatstone Bridge circuit 502 in FIG. 5. In some embodiments, the semiconductor die is mounted on a package substrate (e.g., the package substrate 202 in FIG. 2) prior to implementing the procedure 602. Flow then proceeds to procedure 604.

At the procedure 604, a second measurement signal is transmitted into a second meandering conductive path in a second conductive layer of the BEOL metallization, wherein the second meandering path defines a second long path axis that is substantially orthogonal to the first long path axis. An example of the BEOL metallization is the BEOL metallization 104 in FIG. 1. An example of the second measurement signal is the measurement signal 410 in FIG. 4 and FIG. 5. An example of the second meandering conductive path is the meandering path 406 in FIG. 4 and FIG. 5. An example of the second conductive layer is any other one of the conductive layers M1, M2, M3, or M4 in FIG. 1. An example of the second long path axis is the Y-axis in FIG. 4 and FIG. 5. In some embodiments, the procedure 604 is performed by the Wheatstone Bridge circuit 402 in FIG. 4 or the Wheatstone Bridge circuit 502 in FIG. 5. Flow then proceeds to procedure 606.

At the procedure 606, a first resistance of the first meandering conductive path is detected in response to the transmission of the first measurement signal. In one example of the procedure 606, the Wheatstone Bridge circuit 402 in FIG. 4 or the Wheatstone Bridge circuit 502 in FIG. 5 detect the resistance of the meandering conductive path 404 in FIG. 4 and FIG. 5. Flow then proceeds to procedure 608.

At the procedure 608, a second resistance of the second meandering conductive path is detected in response to the transmission of the second measurement signal. In one example of the procedure 608, the Wheatstone Bridge circuit 402 in FIG. 4 or the Wheatstone Bridge circuit 504 in FIG. 5 detect the resistance of the meandering path 406 in FIG. 4 and FIG. 5. Flow then proceeds to procedure 610.

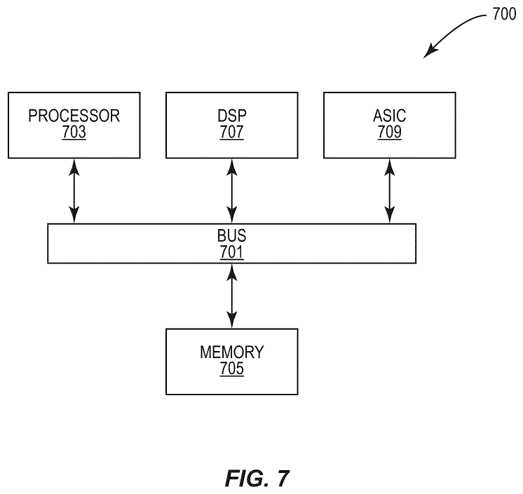

At the procedure 610, a first strain of the semiconductor substrate is determined based on the first resistance, wherein the first strain is measured about a first short path axis substantially orthogonal to the first long path axis. In one example, the procedure 610 is implemented by a computer device 700 to be discussed below in FIG. 7. In one example, the first strain is the strain of the semiconductor substrate 102 (see FIG. 1) about the Y-axis, which is the short path axis of the meandering conductive path 404 in FIG. 4 and FIG. 5. Flow then proceeds to procedure 612.

At the procedure 612, a second strain of the semiconductor substrate is determined based on the second resistance, wherein the second strain is measured about a second short path axis substantially orthogonal to the second long path axis. In one example, the procedure 612 is implemented by a computer device 700 to be discussed below in FIG. 7. In one example, the second strain is the strain of the semiconductor substrate 102 (see FIG. 1) about the X-axis, which is the short path axis of the meandering path 406 in FIG. 4 and FIG. 5. Flow then proceeds to procedure 613.

At the procedure 613, it is determined whether the first strain and the second strain are to be tested when the thickness of the semiconductor substrate is reduced. If the first strain and the second strain are not to be tested when at a thinner thickness, the procedures 602-612 are stopped at procedure 614 (i.e., the stop procedure 614) after the procedure 612. If the first strain and the second strain are to be tested at a thinner thickness, the procedures 602-612 continue to procedure 615.

At the procedure 615, another semiconductor die is obtained with a reduced thickness. The new semiconductor die has a semiconductor substrate that is thinner than the previous semiconductor substrate of the previous semiconductor die.

The procedures 602-612 would be repeated to determine the updated strains based on the updated resistances given the new thickness of the new semiconductor substrate. The procedure 613 would again determine if yet another semiconductor die with a thinner semiconductor substrate should be used. If so, then the procedure 615 and the procedures 602-612 are repeated again. In this manner, the strains at different thicknesses of the semiconductor substrate can be determined. This continuous loop through the procedures 615 and 602-612 would continue until, at the procedure 613, it was decided to implement the stop procedure 614.

FIG. 7 illustrates a computer device 700 (also referred to as a computer 700), in accordance with some embodiments.

The computer device 700 is configured to implement the procedures 610 and 612 in FIG. 6. In addition, the computer device 700 is configured to operate with the Wheatstone Bridge circuit 402 in FIG. 4 and the Wheatstone Bridge circuit 502, 504 in FIG. 5 in order to implement the procedures 602-608 in FIG. 6. In some embodiments, the computer device 700 may also operate with the semiconductor die described in the procedure 615 to reduce the thickness of the semiconductor substrate.

At least one processor 703 and a memory 705 are incorporated in one or more physical packages (e.g., computers). By way of example, a physical package includes an arrangement of one or more materials, components, and/or wires on a structural assembly (e.g., a baseboard) to provide one or more characteristics such as physical strength, conservation of size, and/or limitation of electrical interaction. In certain embodiments, the computer device 700 is implemented in a single computer. In other embodiments, the computer device 700 or the computer 700 is implemented as a single “system on a computer.” In some embodiments, a separate application-specific integrated circuit (ASIC) would not be used, and all relevant functions as disclosed herein would be performed by a processor or processors, e.g., the processor 703. The computer device 700, the computer 700, or a portion thereof constitutes a mechanism for performing one or more steps of designing an IC having a device array free from a set of system design rule constraints.

In one or more embodiments, the computer device 700 or the computer 700 includes a communication mechanism, such as a bus 701, for passing information among the components of the computer device 700. The processor 703 has connectivity to the bus 701 to execute instructions and process information stored in, for example, the memory 705. In some embodiments, the processor 703 is also accompanied with one or more specialized components to perform certain processing functions and tasks. Examples of the specialized components include a digital signal processor (DSP) 707 and an ASIC 709. The DSP 707 typically is configured to process real-world signals (e.g., sound) in real time independently of the processor 703. Similarly, the ASIC 709 is configurable to perform specialized functions not easily performed by a more general-purpose processor. Other specialized components to facilitate performing the functions described herein may optionally include field programmable gate arrays (FPGAs), controllers, or other special-purpose computer computers.

In one or more embodiments, the processor (or multiple processors) 703 performs a set of operations on information as specified by computer program code related to designing an IC having a device array free from a set of system design rule constraints. The computer program code is a set of instructions or statements providing instructions for the operation of the processor 703 and/or the computer system to perform specified functions. The computer program code is stored in the memory 705 or a different type of non-transitory computer readable medium.

The processor 703 and accompanying components have connectivity to the memory 705 via the bus 701. The memory 705 includes one or more of dynamic memory (e.g., random access memory (RAM), magnetic disk, writable optical disk, etc.) and static memory (e.g., read only memory (ROM), CD-ROM, etc.) for storing executable instructions which cause the implementation of the procedures 602-614 in FIG. 6. The memory 705 also stores the data associated with or generated by the execution of the steps.

In one or more embodiments, the memory 705 (such as RAM or any other dynamic storage device) stores information including processor instructions for designing an IC having a device array free from a set of system design rule constraints. Dynamic memory allows information stored therein to be changed by the IC design system. RAM allows a unit of information stored at a location called a memory address to be stored and retrieved independently of information at neighboring addresses. The memory 705 is also used by the processor 703 to store temporary values during execution of processor instructions. In some embodiments, the memory 705 is ROM or any other static storage device coupled to the bus 701 for storing static information, including instructions, that is not changed by the IC design system. Some of the memory 705 is composed of volatile storage that loses the information stored thereon when power is lost. In some embodiments, the memory 705 is a non-volatile (persistent) storage device, such as a magnetic disk, optical disk, or flash card, for storing information, including instructions, that persists even when the IC design system is turned off or otherwise loses power.

The term “non-transitory computer-readable medium” as used herein refers to any medium that participates in providing information to the processor 703, including instructions for execution. Such a medium takes many forms, which include, but are not limited to, a computer-readable storage medium (e.g., non-volatile media, volatile media). Non-volatile media includes, for example, optical or magnetic disks. Volatile media includes, for example, dynamic memory. General forms of computer-readable media include, for example, a floppy disk, a flexible disk, a hard disk, magnetic tape, any other magnetic medium, a CD-ROM, a CDRW, a DVD, any other optical medium, punch cards, paper tape, optical mark sheets, any other physical medium with patterns of holes or other optically recognizable indicia, a RAM, a PROM, an EPROM, a FLASH-EPROM, an EEPROM, a flash memory, any other memory computer or cartridge, or another medium from which a computer can read. The term computer-readable storage medium is used herein to refer to a computer-readable medium.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method of measuring a strain in a semiconductor substrate of a semiconductor die, the semiconductor die further including a Back End of Line (BEOL) metallization on the semiconductor substrate that includes a metallic structure, the method comprising:
transmitting a measurement signal into the metallic structure;
detecting a resistance of the metallic structure in response to the transmission of the measurement signal; and
determining the strain of the semiconductor die based on the resistance of the metallic structure.

2. The method of claim 1, wherein the resistance is a first resistance of the metallic structure and the strain is a first strain of the semiconductor die having a first thickness, the method further comprising:
reducing the first thickness of the semiconductor die to a second thickness that is less than the first thickness;
retransmitting the measurement signal into the metallic structure when the semiconductor die is at the second thickness;
detecting a second resistance of the metallic structure in response to the retransmission of the measurement signal; and
determining a second strain of the semiconductor die based on the second resistance of the metallic structure.

3. The method of claim 2, wherein the second resistance is higher than the first resistance, thereby indicating that the second strain is higher than the first strain.

4. The method of claim 1, wherein the metallic structure comprises a meandering conductive path wherein:
the meandering conductive path defining a long path axis; and
the strain is measured around the long path axis.

5. The method of claim 4, wherein:
the meandering conductive path is a first meandering conductive path;
the long path axis is a first long path axis;
the strain is a first strain;
a strain axis is a first strain axis;
the measurement signal is a first measurement signal; and
the metallic structure further comprises a second meandering conductive path defining a second long path axis that is substantially orthogonal to the first long path axis.

6. The method of claim 5, further comprising:
transmitting a second measurement signal into the second meandering conductive path;
detecting a second resistance of the second meandering conductive path in response to the transmission of the second measurement signal; and
determining a second strain of the semiconductor die based on the second resistance of the second meandering conductive path, wherein the second strain is measured around the second long path axis.

7. The method of claim 6, wherein the first meandering conductive path is positioned in a first conductive layer of the BEOL metallization and the second meandering conductive path is positioned in a second conductive layer of the BEOL metallization.

8. The method of claim 1, wherein detecting the resistance of the metallic structure in response to the transmission of the measurement signal comprises detecting the resistance of the metallic structure in response to the transmission of the measurement signal with a resistance detection circuit.

9. The method of claim 8, wherein the resistance detection circuit has a Wheatstone Bridge configuration.

10. The method of claim 9, wherein the semiconductor die is mounted on a package body and the resistance detection circuit is formed by the metallic structure integrated into the package body.

11. The method of claim 1, further comprising mounting the semiconductor die on a package substrate prior to transmitting the measurement signal into the metallic structure.

12. A method of measuring a strain in a semiconductor substrate of a semiconductor die, the semiconductor die further including a Back End of Line (BEOL) metallization that includes a meandering conductive path, the method comprising:
transmitting a measurement signal into the meandering conductive path, wherein the meandering conductive path defines a long path axis;
detecting a resistance of the meandering conductive path in response to the transmission of the measurement signal; and
determining the strain of the semiconductor die based on the resistance of the meandering conductive path, wherein the strain is measured around the long path axis.

13. The method of claim 12, wherein the meandering conductive path comprises:
a first plurality of conductive segments, each of the first plurality of conductive segments has a long segment axis that extends parallel to the long path axis; and
a second plurality of conductive segments, each of the second plurality of conductive segments connects different pairs of the first plurality of conductive segments.

14. The method of claim 13, wherein the meandering conductive path is positioned in a first conductive layer of the BEOL metallization.

15. The method of claim 12, further comprising:
transmitting a second measurement signal into a second meandering conductive path in the BEOL metallization, wherein:
the meandering conductive path is a first meandering conductive path;
the long path axis is a first long path axis;
the measurement signal is a first measurement signal; and
the second meandering conductive path defines a second long path axis substantially orthogonal to the first long path axis;
detecting a second resistance of the second meandering conductive path in response to the transmission of the second measurement signal, wherein the resistance is a first resistance; and
determining a second strain of the semiconductor die based on the second resistance of the second meandering conductive path, wherein the second strain is measured around the second long path axis, wherein the strain is a first strain.

16. The method of claim 15, wherein:
the first meandering path is in a first conductive layer of the BEOL; and
the second meandering conductive path is in a second conductive layer of the BEOL metallization.

17. The method of claim 15, wherein:
transmitting the first measurement signal into the first meandering conductive path comprises transmitting the first measurement signal into the first meandering conductive path with a first Wheatstone Bridge circuit; and
transmitting the second measurement signal into the second meandering conductive path comprises transmitting the second measurement signal into the second meandering conductive path with a second Wheatstone Bridge circuit.

18. The method of claim 15, wherein:
transmitting the first measurement signal into the first meandering conductive path comprises transmitting the first measurement signal into the first meandering conductive path with a Wheatstone Bridge circuit; and
transmitting the second measurement signal into the second meandering conductive path comprises transmitting the second measurement signal into the second meandering conductive path with the Wheatstone Bridge circuit.

19. The method of claim 12, wherein:
the semiconductor die is mounted on a package body;
transmitting the measurement signal into the meandering conductive path comprises transmitting the measurement signal into the meandering conductive path with a Wheatstone Bridge circuit; and
the Wheatstone Bridge circuit is formed in a conductive structure integrated into the package body.

20. The method of claim 12, further comprising mounting the semiconductor die on a package substrate prior to transmitting the measurement signal into the meandering conductive path.
